(19) United States
(12) Patent Application Publication
(10) Pub. No.: US 2026/0351156 A1
(43) Pub. Date: Nov. 5, 2026

(54) ARRAY SUBSTRATE, DISPLAY APPARATUS, AND DRIVING METHOD

(71) Applicants: Beijing BOE Display Technology Co., Ltd., Beijing (CN); BOE Technology Group Co., Ltd., Beijing (CN)

(72) Inventors: Tao YANG, Beijing (CN); Yingmeng MIAO, Beijing (CN); Dongchuan CHEN, Beijing (CN); Yanping LIAO, Beijing (CN); Yue YANG, Beijing (CN)

(21) Appl. No.: 19/485,953

(22) PCT Filed: May 22, 2024
(86) PCT No.: PCT/CN2024/094712

§ 371 Date: Nov. 19, 2025

(30) Foreign Application Priority Data
Jun. 29, 2023 (CN) 202310791962.2

(51) Int. Cl. G09G 3/20; G11C 19/28; H10D 86/40

(52) U.S. Cl. CPC G09G 3/2092; G11C 19/28; H10D 86/441; G09G 2300/0452; G09G 2310/0286; G09G 2310/08; G09G 2320/0242; G09G 2320/06

(57) ABSTRACT

Disclosed are an array substrate, a display apparatus, and a driving method. The array substrate includes: gate lines and data lines, each sub-pixel row defined by the gate lines and the data lines intersecting each other includes a pixel electrode and a transistor, and the edge of the pixel electrode that extends along a gate line is longer than the edge thereof that extends along a data line; two adjacent sub-pixel rows having the same color form one row unit; two shift registers are arranged adjacent to each other or two shift registers are spaced apart from each other by (M−1) shift registers, one register group corresponds to one row unit, the first shift register in the register group is connected to the first sub-pixel row in the corresponding row unit, and the second shift register is connected to the second sub-pixel row in the corresponding row unit.

### CROSS-REFERENCE TO RELATED APPLICATIONS

This application claims priority to the Chinese patent application filed with China National Intellectual Property Administration Jun. 29, 2023, with application number 202310791962.2 and application name “An array substrate, display device and driving method”, all contents of which are incorporated by reference in this application.

### TECHNICAL FIELD

The present disclosure relates to the field of display technology and provides an array substrate, a display apparatus and a driving method.

### BACKGROUND

The use of triple-gate pixel architecture can reduce the number of data lines by two-thirds, and accordingly, the amount of data driver chips used will also be reduced by two-thirds, thereby reducing the cost of the display panel. DLG technology can double the refresh rate, but under the triple-gate pixel architecture design, the colors of two adjacent sub-pixels connected to the same data line are different. In the DLG mode, there will be a problem of displaying multiple colors at the same time, resulting in abnormal colors of the displayed screen, that is, in the DLG mode with doubled refresh rate, two different colors will be displayed within the corresponding display time of the sub-pixel.

### SUMMARY

The embodiments of the present disclosure provide an array substrate, a display device and a driving method, which are used to improve the display effect of a picture, and increase the charging rate of the array substrate while reducing the cost. The specific technical solutions provided by this disclosure are as follows.

In the first aspect, some embodiments of the present disclosure provided an array substrate, including: a display region and a non-display region, the display region includes a plurality of rows of gate lines and a plurality of columns of data lines, the plurality of rows of gate lines and the plurality of columns of data lines intersect to define a plurality of sub-pixel rows, the sub-pixel rows include pixel electrodes and transistors, a side of a pixel electrode extending along the gate lines is longer than a side of the pixel electrode extending along the data lines; the non-display region includes a plurality of cascaded shift registers; the display region includes a plurality of row groups repeatedly arranged along a column direction, each of the row groups includes: M sub-pixel rows of different colors arranged along the column direction, and sub-pixels in a same sub-pixel row are of a same color; two sub-pixel rows of the same color in two adjacent row groups form one of row units; the plurality of cascaded shift registers include a plurality of register groups, each of the register groups includes two shift registers, wherein the two shift registers are arranged adjacent to each other, or there are M−1 shift registers between the two shift registers; one of the register groups corresponds to one of the row units; a first shift register in a register group is connected to a first sub-pixel row in a row unit corresponding to the register group, and a second shift register in the register group is connected to a second sub-pixel row in the row unit corresponding to the register group; the array substrate further includes a plurality of clock signal lines, and each of the cascaded shift registers is connected to a respective one of the clock signal lines; based on that the array substrate operating in a first mode, clock signals on clock signal lines connected to a same register group are the same, and clock signals on clock signal lines connected to two adjacent register groups are of a first phase difference.

In some embodiments, an operating mode of the array substrate further includes a second mode; based on that the array substrate operating in the second mode, the clock signals on the clock signal lines connected to the same register group are of a second phase difference, and the clock signals on the clock signal lines connected to the two adjacent register groups are of the second phase difference.

In some embodiments, the first phase difference is twice the second phase difference.

In some embodiments, a width of a data signal loaded into the row unit is 2H, wherein H is a charging time of one sub-pixel row.

In some embodiments, each of the row groups includes: a first color sub-pixel row, a second color sub-pixel row, and a third color sub-pixel row arranged along the column direction;
based on that the array substrate operating in the first mode, a timing of a clock signal corresponding to a shift register connected to the first color sub-pixel row is earlier than a timing of a clock signal corresponding to a shift register connected to the second color sub-pixel row, and the timing of the clock signal corresponding to the shift register connected to the second color sub-pixel row is earlier than a timing of a clock signal corresponding to a shift register connected to the third color sub-pixel row.

In some embodiments, connection relationships between shift registers and clock signal lines are as follows:
a 12k-11th-level shift register is connected to a first clock signal line of the plurality of clock signal lines;
a 12k-10th-level shift register is connected to a second clock signal line of the plurality of clock signal lines;
a 12k-9th-level shift register is connected to a third clock signal line of the plurality of clock signal lines;
a 12k-8th-level shift register is connected to a fourth clock signal line of the plurality of clock signal lines;
a 12k-7th-level shift register is connected to a fifth clock signal line of the plurality of clock signal lines;
a 12k-6th-level shift register is connected to a sixth clock signal line of the plurality of clock signal lines;
a 12k-5th-level shift register is connected to a seventh clock signal line of the plurality of clock signal lines;
a 12k-4th-level shift register is connected to an eighth clock signal line of the plurality of clock signal lines;
a 12k-3th-level shift register is connected to a ninth clock signal line of the plurality of clock signal lines;
a 12k-2th-level shift register is connected to a tenth clock signal line of the plurality of clock signal lines;
a 12k-1th-level shift register is connected to an eleventh clock signal line of the plurality of clock signal lines;
a 12kth-level shift register is connected to a twelfth clock signal line of the multiple clock signal lines, k is a positive integer.

In some embodiments, the array substrate further including at least two gate driving circuits, wherein the gate driving circuits include the plurality of cascaded shift registers;
an input signal terminal of a first-level shift register is configured to be coupled to a frame initial signal terminal;
in every six adjacent shift registers, an input signal terminal of a 6Mth-level shift register is configured to be coupled to an output terminal of a 6M−5th-level shift register, and a reset signal terminal of the 6M−5th-level shift register is configured to be coupled to an output terminal of a 6M+Nth-level shift register, M is a positive integer and N is a positive integer.

In some embodiments, the array substrate further including a first initial signal line, wherein the first initial signal line is coupled to the frame initial signal terminal;
input signal terminals of the first-level shift register to a 2Mth-level shift register are connected to the first initial signal line.

In some embodiments, the array substrate further including a second initial signal line and a third initial signal line, wherein the second initial signal line is coupled to a first frame initial signal terminal, and the third initial signal line is coupled to a second frame initial signal terminal;
input signal terminals of the first-level shift register to a Mth-level shift register are connected to the second initial signal line, and input signal terminals of the Mth-level shift register to a 2Mth-level shift register is connected to the third initial signal line.

In some embodiments, sub-pixels located in different rows and connected to a same data line are arranged on both sides of the same data line.

In some embodiments, sub-pixels in different rows and connected to a same data line are arranged on a same side of the same data line.

In the second aspect, some embodiments provides a display device, including the aforementioned array substrate.

In the third aspect, some embodiments provides a driving method, including:
in a first mode, loading a same clock signal onto clock signal lines connected to a same register group, and loading clock signals with a first phase difference onto clock signal lines connected to two adjacent register groups.

The beneficial effects of the present disclosure are as follows.

In summary, in the embodiments of the present disclosure, an array substrate, a display device and a driving method are provided, the array substrate includes: a display region and a non-display region, the display region includes a plurality of rows of gate lines and a plurality of columns of data lines, the plurality of rows of gate lines and the plurality of columns of data lines cross to define a plurality of sub-pixel rows, the sub-pixel rows include pixel electrodes and transistors, the sides of the pixel electrodes extending along the gate lines are larger than the sides of the data lines extending, the non-display region includes a plurality of cascaded shift registers, and the display region includes a plurality of row groups repeatedly arranged along the column direction, each row group includes: M sub-pixel rows of different colors arranged along the column direction, the sub-pixels in the same sub-pixel row have the same color, and two sub-pixel rows of the same color in two adjacent row groups form a row unit, and the plurality of cascaded shift registers includes multiple register groups, each register group includes two shift registers, the two shift registers are adjacently arranged or there are M−1 shift registers between the two shift registers, one register group corresponds to one row unit, the first shift register in the register group is connected to the first sub-pixel row in the corresponding row unit, and the second shift register is connected to the second sub-pixel row in the corresponding row unit. The array substrate also includes multiple clock signal lines, each shift register is connected to a clock signal line, when the array substrate works in the first mode, the clock signals on the clock signal lines connected to the same register group are the same, and the clock signals on the clock signal lines connected to two adjacent register groups have a first phase difference. The above-mentioned method of connecting the sub-pixel rows of the same color that are opened in sequence by the same data line and driving the above-mentioned sub-pixel rows of the same color by the same clock signal effectively improves the display effect of the picture, while reducing the cost, and improving the charging rate of the array substrate.

Other features and advantages of the present disclosure will be described in the following description, and partly become apparent from the description, or be understood by practicing the present disclosure. The purpose and other advantages of the present disclosure can be realized and obtained by the structures particularly pointed out in the written description, claims, and drawings.

### BRIEF DESCRIPTION OF FIGURES

The drawings described herein are used to provide a further understanding of the present disclosure and constitute a part of the present disclosure. The illustrative embodiments of the present disclosure and their descriptions are used to explain the present disclosure and do not constitute an improper limitation on the present disclosure. In the drawings:

FIG. 1 is a schematic diagram of connecting an array substrate in an embodiment of the present disclosure;

FIG. 2 is a schematic diagram of a first triple gate pixel architecture in an embodiment of the present disclosure;

FIG. 3 is a schematic diagram of a second triple gate pixel architecture in an embodiment of the present disclosure;

FIG. 4 is a schematic diagram of the connection relationship between the output of the shift register in the non-display region and each sub-pixel in the display region in the first embodiment of the present disclosure;

FIG. 5 is a schematic diagram of data signal input when the array substrate is in the first mode in the first embodiment of the present disclosure;

FIG. 6 is a schematic diagram of data signal input when the array substrate is in the second mode in the first embodiment of the present disclosure;

FIG. 7 is a connection diagram of a cascade relationship of the shift registers in the first embodiment of the present disclosure;

FIG. 8 is a schematic diagram of a driving timing input when the array substrate is in the first mode in the first embodiment of the present disclosure;

FIG. 9 is a schematic diagram of a driving timing input when the array substrate is in the second mode in the first embodiment of the present disclosure;

FIG. 10 is a schematic diagram of the connection relationship between the outputs of the shift registers in the non-display region and each sub-pixel in the display region in the second embodiment of the present disclosure;

FIG. 11 is a schematic diagram of a driving timing input when the array substrate is in the first mode in the second embodiment of the present disclosure;

FIG. 12 is a schematic diagram of a driving timing input when the array substrate is in the second mode in the first embodiment of the present disclosure;

FIG. 13 is a schematic diagram of data signal input when the array substrate is in the first mode in the first embodiment of the present disclosure;

FIG. 14 is a schematic diagram of data signal input when the array substrate is in the second mode in the first embodiment of the present disclosure;

FIG. 15 is a connection diagram of a cascade relationship of shift registers in a second embodiment of the present disclosure;

FIG. 16 is a connection diagram of another cascade relationship of shift registers in the second embodiment of the present disclosure.

### DETAILED DESCRIPTION

In order to make the purpose, technical solution and advantages of the embodiments of the present disclosure clearer, the technical solution of the present disclosure will be clearly and completely described below in conjunction with the drawings in the embodiments of the present disclosure. Obviously, the described embodiments are part of the embodiments of the technical solution of the present disclosure, rather than all the embodiments. Based on the embodiments recorded in the present disclosure document, all other embodiments obtained by ordinary technicians in this field without creative work are within the scope of protection of the technical solution of the present disclosure.

The terms “first”, “second”, etc. in the specification and claims of the present disclosure and the above-mentioned drawings are used to distinguish similar objects, and are not necessarily used to describe a specific order or sequence. It should be understood that the numbers used in this way can be interchanged where appropriate, so that the embodiments of the present invention described herein can be implemented using sequences other than those illustrated or described herein.

The preferred embodiments of the present disclosure are described in detail below with reference to the accompanying drawings.

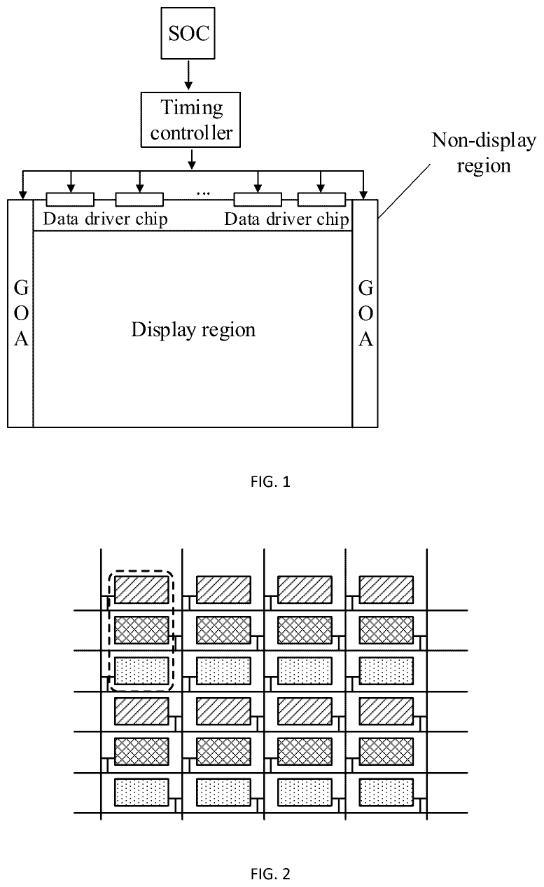

An array substrate proposed in an embodiment of the present disclosure, as shown in FIG. 1, includes: a display region and a non-display region, the display region includes a plurality of rows of gate lines and a plurality of columns of data lines. The plurality of rows of gate lines and the plurality of columns of data lines intersect to define a plurality of sub-pixel rows. The sub-pixel rows include pixel electrodes and transistors, and the side of the pixel electrode extending along the gate lines is longer than the side of the pixel electrode extending along the data lines.

First of all, it should be explained that the peripheral circuit of the array substrate usually includes a system on chip (SOC), a timing controller and a data driver chip. Of course, in practical applications, the implementation method of the SOC can be determined according to the needs of the practical application, and is not limited here. The above-mentioned timing controller can store an overdrive relationship table, etc., and perform display control during the display process of the screen of the display panel. The number of the above-mentioned data driver chips is usually multiple, and each data driver chip is used to provide a data voltage for the sub-pixels of the display region to achieve color display of the screen.

In the embodiment of the present disclosure, the array substrate includes a display region and a non-display region. The display region mainly realizes the display of the picture through multiple sub-pixel rows. The above-mentioned display region includes multiple rows of gate lines and multiple columns of data lines. The multiple rows of gate lines and multiple columns of data lines cross to define multiple sub-pixel rows. Each sub-pixel is controlled by the gate line and the data line. The sub-pixel row includes a pixel electrode and a transistor. During the display process, the gate line controls the conduction of the transistor through the gate signal, and the data line provides a data signal to the pixel electrode through the conducted transistor.

It should be noted that the array substrate in the embodiment of the present disclosure is a triple gate pixel architecture, and the side of the pixel electrode extending along the gate line is longer than the side of the pixel electrode extending along the data line, that is, the horizontal side length of the array substrate in the embodiment of the present disclosure is greater than the vertical side length of the array substrate. It should be noted that when the pixel electrode is a plate-shaped electrode, the side of the pixel electrode extending along the gate line is longer than the side of the pixel electrode extending along the data line. When the pixel electrode is a structure with a slit and a branch electrode, the edge connection line of the pixel electrode formed by a plurality of branch electrodes serves as the side of the pixel electrode extending along the gate line.

The non-display region includes a plurality of cascaded shift registers GOA.

In the embodiment of the present disclosure, optionally, a plurality of shift registers are evenly distributed on both sides of the display region, and the gate signal in the above-mentioned gate line is provided by the corresponding GOA, or the shift registers are set on one side of the non-display region, which is not limited here.

The display region is described in detail below. The display region includes a plurality of row groups repeatedly arranged along the column direction. Each row group includes: M sub-pixel rows with different colors arranged along the column direction. Sub-pixels in the same sub-pixel row have the same color.

In the embodiment of the present disclosure, each sub-pixel included in the display region is first divided into row groups, that is, in units of columns, M sub-pixel rows with different red, green and blue colors arranged along the column direction are called a group, and the value of the above M is usually at least three. In the sub-pixel rows including red, green, blue and white, the minimum value of the above M is usually four. In the above row group, the sub-pixels in the same sub-pixel row have the same color, that is, at least three or four sub-pixel rows with different colors in a certain column form a row group.

Two sub-pixel rows of the same color in the two adjacent row groups form a row unit.

Considering that sub-pixels of different colors are arranged sequentially in a row group, in the embodiment of the present disclosure, two sub-pixels of the same color in two adjacent row groups are called a row unit.

Since the shift registers correspond to the sub-pixel rows one by one, the multiple cascaded shift registers include multiple register groups. Each register group includes two shift registers, and the two shift registers are adjacently arranged or there are M−1 shift registers between the two shift registers.

One register group corresponds to one row unit.

The first shift register in the register group is connected to the first sub-pixel row in the corresponding row unit, and the second shift register is connected to the second sub-pixel row in the corresponding row unit.

In an embodiment of the present disclosure, after two adjacent row groups are divided into a row unit, each shift register is also divided, that is, two shift registers are divided into a register group, so that one register group corresponds to one row unit, and each shift register in the register group corresponds to a sub-pixel row.

In order to realize simultaneous charging of sub-pixels of the same color connected to the same data line, two schemes are provided in the embodiments of the present disclosure: Scheme 1, two shift registers are arranged adjacent to each other, that is, the two adjacent shift registers are divided into a register group; Scheme 2, there are M−1 shift registers between the two shift registers, that is, the two shift registers corresponding to two sub-pixel rows of the same color are divided into a register group.

In order to display the picture normally, the array substrate further includes a plurality of clock signal lines, and each shift register is connected to a clock signal line, that is, the shift register is started under the driving control of the clock signal line.

When the array substrate operates in the first mode, the clock signals on the clock signal lines connected to the same register group are the same, and the clock signals on the clock signal lines connected to two adjacent register groups have a first phase difference.

It should be noted that the first mode is the DLG mode. In the first mode, the clock signals on the clock signal lines connected to the two shift registers in the same register group are the same, so that the gate lines of the two shift registers in the same register group can simultaneously provide drive signals to the two sub-pixel rows of the same color included in the corresponding row unit. In order to make the entire array substrate work normally, the clock signals on the clock signal lines connected to the two adjacent register groups have a first phase difference, so that the two adjacent registers can provide drive signals to the two adjacent sub-pixel rows of different colors in a time-sharing manner, thereby ensuring the row-by-row driving of each sub-pixel row.

In addition, there are two ways to arrange the sub-pixels and the connected data lines in the embodiments of the present disclosure. The first way is shown in FIG. 2. The sub-pixels located in different rows connected to the same data line are arranged on both sides of the same data line. Optionally, referring to FIG. 2, the three sub-pixels from top to bottom surrounded by dotted lines can be sub-pixels corresponding to red, green and blue respectively, and the sub-pixels in the same row have the same color.

In the embodiment of the present disclosure, sub-pixels located in different rows and the connected data lines are arranged in a zigzag shape, that is, sub-pixels located in different rows connected to the same data line are arranged on both sides of the same data line.

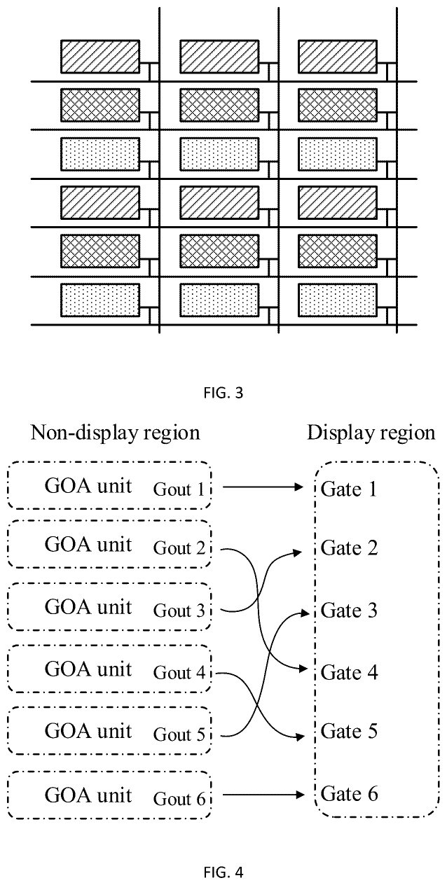

The second method is shown in FIG. 3, where sub-pixels in different rows connected to the same data line are arranged on the same side of the same data line.

In the embodiment of the present disclosure, sub-pixels located in different rows are arranged in a straight line with the data lines connected thereto, that is, sub-pixels located in different rows connected to the same data line are arranged on the same side of the same data line. Compared with the method shown in FIG. 2, in the second method, since the sub-pixels driven at the same time are located on the same side of the same data line, the color display is more uniform and the display effect is better.

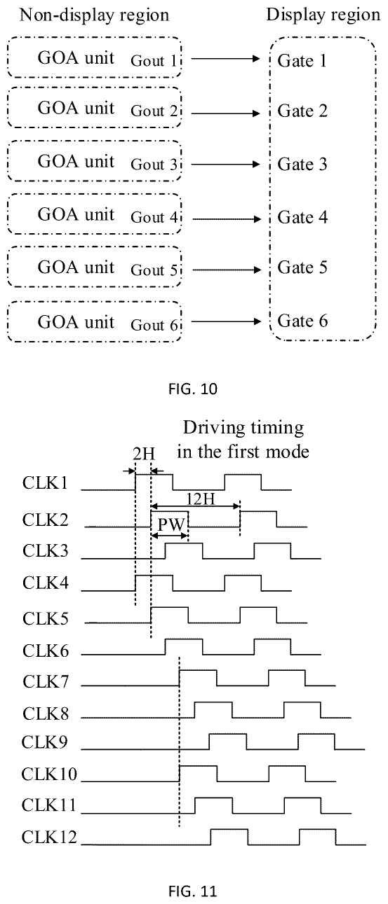

After introducing the basic structure of the array substrate in the embodiment of the present disclosure, two schemes provided in the embodiment of the present disclosure are described in detail below. As shown in FIG. 4, in scheme 1, two shift registers are arranged adjacent to each other. Referring to FIG. 10, there are M−1 shift registers between the two shift registers in scheme 2. Both scheme 1 and scheme 2 can realize that two sub-pixels of the same color corresponding to the same register group are turned on and charged at the same time, that is, at the same moment, the gate line controls two sub-pixel rows of the same color to be turned on at the same time and the same data signal is charged into the above two sub-pixels by the data line.

Referring to FIG. 4, the specific approach of scheme 1 is to change the connection relationship between the outputs of the shift registers in the non-display region and each sub-pixel in the display region. For example, six sub-pixels including red, green and blue are arranged along the column direction as shown in FIG. 4. The first sub-pixel has the same color as the fourth sub-pixel, the second sub-pixel has the same color as the fifth sub-pixel, and the third sub-pixel has the same color as the sixth sub-pixel. The first sub-pixel and the fourth sub-pixel form a row unit, the second sub-pixel and the fifth sub-pixel form a row unit, and the third sub-pixel and the sixth sub-pixel form a row unit.

Correspondingly, in order to correspond to the row unit, the shift register connected to the first sub-pixel and the shift register connected to the fourth sub-pixel in the non-display region are in one register group, the shift register connected to the second sub-pixel and the shift register connected to the fifth sub-pixel are in one register group, and the shift register connected to the third sub-pixel and the shift register connected to the sixth sub-pixel are in one register group. Each register group is connected to the sub-pixel row in the corresponding row unit through the connection shown in FIG. 4.

Referring to FIG. 5, it should be noted that, in the first mode of the scheme 1, the width of the data signal loaded into the same row unit is 2H, where H is the charging time of a row of sub-pixels. Referring to FIG. 5, Gout 1 and Gout 4 are turned on as a group at the same time, and then Gout 2 and Gout 5, Gout 3 and Gout 6, and so on are turned on in sequence, and the details are not repeated here.

During the implementation process, the width of the time for writing the data signal into the sub-pixel row is 2H, that is, the driving method at this time can increase the charging time of the pixel row, which is suitable for high-resolution products.

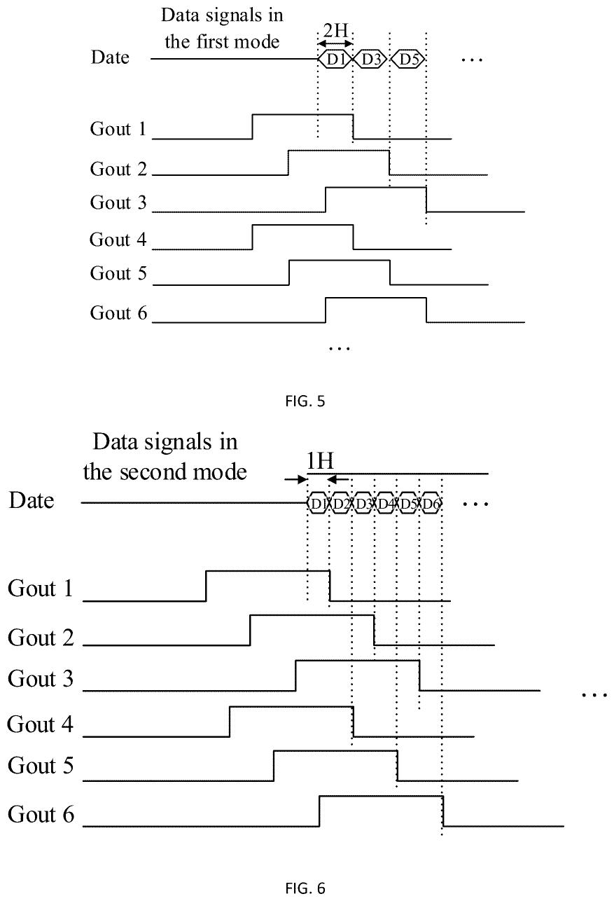

Referring to FIG. 6, it should be noted that in the second mode of the scheme 1, the second mode generally refers to a non-DLG mode, and the width of the data signal loaded into a row of sub-pixels is 1H. Referring to FIG. 6, the order in which the gate lines are turned on is Gout 1, Gout 4, Gout 2, Gout 5, Gout 3, and Gout 6, and the phase difference in the timing of turning-on of adjacent gate lines is 1H, that is, Gout 4 is turned on 1H later than Gout 1, Gout 2 is turned on 1H later than Gout 4, and so on.

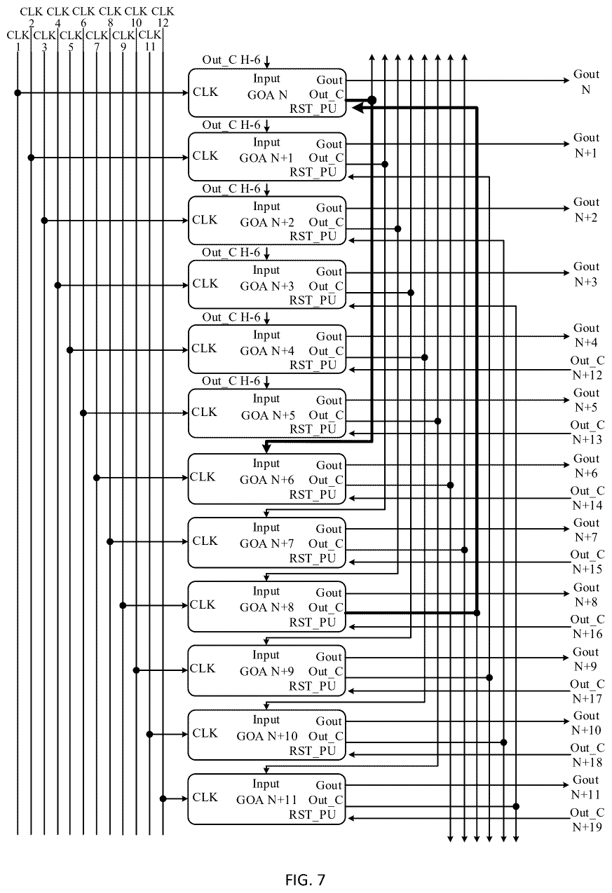

Specifically, referring to FIG. 7, the working mode of the array substrate also includes a second mode.

When the array substrate operates in the second mode, clock signals on the clock signal lines connected to the same register group have a second phase difference, and clock signals on the clock signal lines connected to two adjacent register groups have a second phase difference.

During implementation, when the array substrate operates in a non-DLG mode, the clock signals on the clock signal lines connected to the two shift registers in the same register group have a second phase difference, which can ensure that the gate lines of the two shift registers in the same register group can provide driving signals to the two sub-pixel rows of the same color included in the corresponding row unit at equal time intervals. In order to make the display screen of the entire array substrate more uniform, the clock signals on the clock signal lines connected to the two adjacent register groups also have a second phase difference, so that the two adjacent registers can provide driving signals to the two adjacent sub-pixel rows of different colors at equal time intervals, thereby ensuring the row-by-row driving of each sub-pixel row.

Since the refresh rate is doubled in the DLG mode, the first phase difference is twice the second phase difference.

Still taking the two register groups including six sub-pixel rows of red, green and blue as an example for explanation, it can be seen from FIG. 7 that in scheme 1, the cascade relationship between the shift registers is: the cascade output signal Out_C of the first shift register is connected to the input terminal Input of the seventh shift register, and the cascade output signal Out_C of the second shift register is connected to the input terminal Input of the eighth shift register. Optionally, the present scheme is provided with a cascade output terminal Out_C and a gate signal output terminal Gout, where the cascade output terminal Out_C is used to transmit the cascade carry and reset signals, and the gate signal output terminal Gout is used to electrically connect to the gate line of the display region and transmit the gate turn-on signal. Of course, the present scheme may also be provided with only a gate signal output terminal Gout, that is, the gate signal output terminal Gout is used to transmit the cascade carry and reset signals and transmit the gate line turn-on signal of the display region. Referring to FIG. 7, in this case, the cascade output terminal of the Nth-level GOA (GOA N) is used to provide a signal to the input terminal of GOA N+6, and the cascade output terminal of GOA N+8 is used to provide a reset signal to GOA N, and the subsequent registers are analogous. At the same time, the output signal of the shift register after the sixth shift register is connected to the reset terminal of the first shift register, and the output signal of the shift register after the seventh shift register is connected to the reset terminal of the second shift register, and so on.

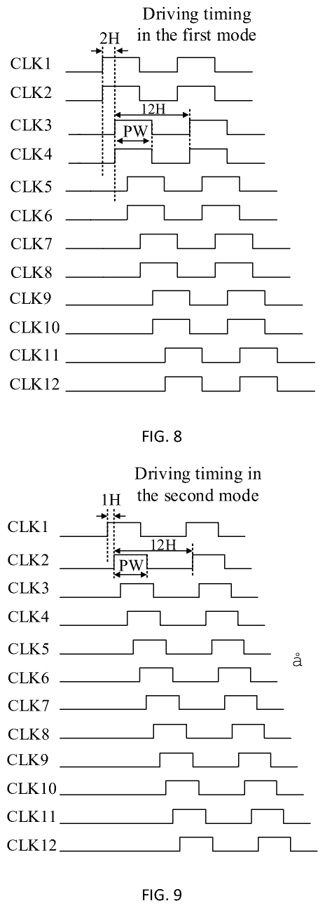

Specifically, the clock signals corresponding to each sub-pixel row in the first mode in the embodiment of the present disclosure are shown in FIG. 8, that is, in the DLG mode, the clock signals corresponding to the sub-pixels in the latter row of each adjacent row are 2H later than the clock signals corresponding to the sub-pixels in the previous row. Referring to FIG. 8, during the implementation process, there is no need to make special adjustments to the clock signal in the DLG mode, only the correspondence between the output terminal of the GOA and the gate line needs to be adjusted (that is, CLK1 and CLK2 can be turned on at the same time, and the second GOA corresponding to CLK2 is electrically connected to the 4th gate line of the display panel) to realize the DLG function of the triple Gate, which ensures cost reduction and improves the charging rate of the display panel.

Specifically, the clock signals corresponding to each sub-pixel row in the second mode in the embodiment of the present disclosure are shown in FIG. 9, that is, in the DLG mode, the clock signal corresponding to the next row of sub-pixels in each adjacent row is 1H later than the clock signal corresponding to the previous row of sub-pixels.

After introducing the scheme 1, the scheme 2 in the embodiment of this disclosure is introduced in detail.

Referring to FIG. 10, unlike the scheme 1, the connection relationship between the outputs of the shift registers in the non-display region and the sub-pixels in the display region is not changed. For example, as shown in FIG. 1, six sub-pixels including red, green and blue are arranged along the column direction. The first sub-pixel has the same color as the fourth sub-pixel, the second sub-pixel has the same color as the fifth sub-pixel, and the third sub-pixel has the same color as the sixth sub-pixel. The first sub-pixel and the fourth sub-pixel form a row unit, the second sub-pixel and the fifth sub-pixel form a row unit, and the third sub-pixel and the sixth sub-pixel form a row unit.

The shift register connected to the first sub-pixel and the shift register connected to the fourth sub-pixel in the non-display region form a register group, the shift register connected to the second sub-pixel and the shift register connected to the fifth sub-pixel form a register group, and the shift register connected to the third sub-pixel and the shift register connected to the sixth sub-pixel form a register group. Each register group is connected to the sub-pixel row in the corresponding row unit through the connection shown in FIG. 10, that is, the shift registers are connected to the sub-pixel rows in a one-to-one correspondence.

In the embodiment of the present disclosure, the connection relationships between the shift registers and the clock signal lines is as follows.
The 12k-11th shift register is connected to the first clock signal line of the plurality of clock signal lines.
The 12k-10th-level shift register is connected to the second clock signal line of the plurality of clock signal lines.
The 12k-9th-level shift register is connected to the third clock signal line of the plurality of clock signal lines.
The 12k-8th-level shift register is connected to the fourth clock signal line of the plurality of clock signal lines.
The 12k-7th-level shift register is connected to the fifth clock signal line of the plurality of clock signal lines.
The 12k-6th-level shift register is connected to the sixth clock signal line of the plurality of clock signal lines.
The 12k-5th-level shift register is connected to the seventh clock signal line of the plurality of clock signal lines.
The 12k-4th-level shift register is connected to the eighth clock signal line of the plurality of clock signal lines.
The 12k-3-level shift register is connected to the ninth clock signal line of the plurality of clock signal lines.
The 12k-2-level shift register is connected to the tenth clock signal line of the plurality of clock signal lines.
The 12k-1th-level shift register is connected to the eleventh clock signal line of the plurality of clock signal lines.
The 12k-th-level shift register is connected to the twelfth clock signal line of the plurality of clock signal lines, where k is a positive integer.

During the implementation, assuming that k is 1, the first-stage shift register in scheme 2 is connected to the first clock signal line of the plurality of clock signal lines, the second-stage shift register is connected to the second clock signal line of the plurality of clock signal lines . . . and so on.

Referring to FIG. 11, in the embodiment of the present disclosure, the driving timing of CLK is changed based on the connection relationships of FIG. 10. As shown in FIG. 11, taking the case of 12 sub-pixel rows as an example, the first row of sub-pixel rows and the fourth row of sub-pixel rows have the same color, and the timing of the clock signals corresponding to the shift registers connected to these two sub-pixel rows are the same. The second row of sub-pixel rows and the fifth row of sub-pixel rows have the same color, and the timing of the clock signals corresponding to the shift registers connected to these two sub-pixel rows are the same, and so on.

Specifically, each row group includes: a first color sub-pixel row, a second color sub-pixel row, and a third color sub-pixel row arranged along a column direction.

When the array substrate operates in the first mode, the timing of the clock signal corresponding to the shift register connected to the first color sub-pixel row is earlier than the timing of the clock signal corresponding to the shift register connected to the second color sub-pixel row, and the timing of the clock signal corresponding to the shift register connected to the second color sub-pixel row is earlier than the timing of the clock signal corresponding to the shift register connected to the third color sub-pixel row.

During implementation, when the array substrate operates in DLG mode, the timing of the clock signal corresponding to the shift register connected to the first color sub-pixel row, the clock signal corresponding to the shift register connected to the second color sub-pixel row, and the clock signal corresponding to the shift register connected to the third color sub-pixel row are incremented by 2H in sequence.

It should be supplemented that the sub-pixel color of the first color sub-pixel row is red, the sub-pixel color of the second color sub-pixel row is green, and the sub-pixel color of the first color sub-pixel row is blue.

Alternatively, the sub-pixel color of the first color sub-pixel row is green, the sub-pixel color of the second color sub-pixel row is blue, and the sub-pixel color of the first color sub-pixel row is red.

Alternatively, the sub-pixel color of the first color sub-pixel row is blue, the sub-pixel color of the second color sub-pixel row is red, and the sub-pixel color of the first color sub-pixel row is green.

Alternatively, the sub-pixel color of the first color sub-pixel row is red, the sub-pixel color of the second color sub-pixel row is blue, and the sub-pixel color of the first color sub-pixel row is green.

Alternatively, the sub-pixel color of the first color sub-pixel row is green, the sub-pixel color of the second color sub-pixel row is red, and the sub-pixel color of the first color sub-pixel row is blue.

Alternatively, the sub-pixel color of the first color sub-pixel row is blue, the sub-pixel color of the second color sub-pixel row is green, and the sub-pixel color of the first color sub-pixel row is red.

That is, during the implementation, the sub-pixel color of the first color sub-pixel row, the sub-pixel color of the second color sub-pixel row, and the sub-pixel color of the third color sub-pixel row are random, and the colors corresponding to the sub-pixels are not specifically limited.

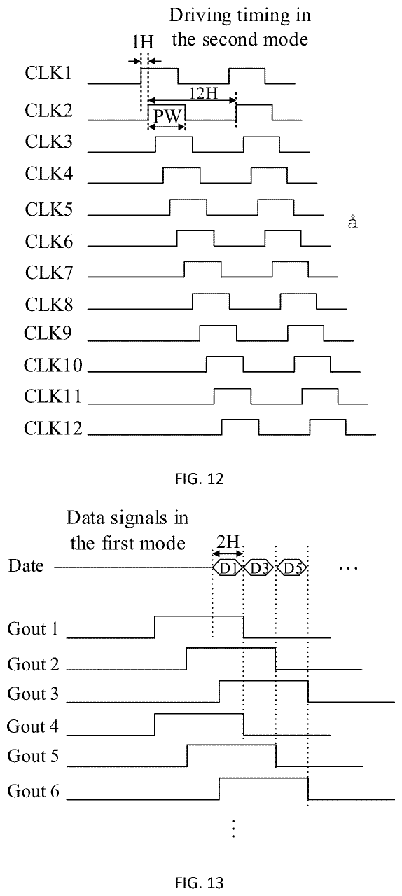

Referring to FIG. 12, during the implementation process, when the array substrate operates in non-DLG mode, the timing of the clock signal corresponding to the shift register connected to the first color sub-pixel row, the timing of the clock signal corresponding to the shift register connected to the second color sub-pixel row, and the timing of the clock signal corresponding to the shift register connected to the third color sub-pixel row are successively increased by 1H.

Referring to FIG. 13, in order to charge the same data signal to the data lines corresponding to the two sub-pixel rows of the same color, in the embodiment of the present disclosure, when the array substrate works in the DLG mode, the data signal on the data line is first input to the first row of sub-pixel rows corresponding to the first shift register and the fourth row of sub-pixel rows corresponding to the fourth shift register, and then to the first row of sub-pixel rows corresponding to the second shift register and the fifth row of sub-pixel rows corresponding to the fifth shift register, and then to the third row of sub-pixel rows corresponding to the third shift register and the sixth row of sub-pixel rows corresponding to the sixth shift register. During the implementation, the width of the time for the data signal to be written into a sub-pixel row is 2H.

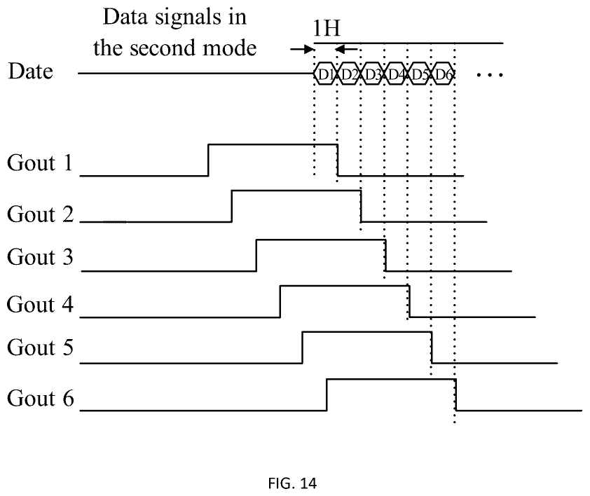

Referring to FIG. 14, when the array substrate operates in the non-DLG mode, in order to charge the same data signal into the data lines corresponding to two sub-pixel rows of the same color, in the embodiment of the present disclosure, the data signals on the data lines will be written in the order of the arrangement of the shift registers, that is, the first shift register, the second shift register, the third shift register . . . In the non-DLG mode, the time width for the data signal to be written into the sub-pixel row corresponding to a shift register is 1H.

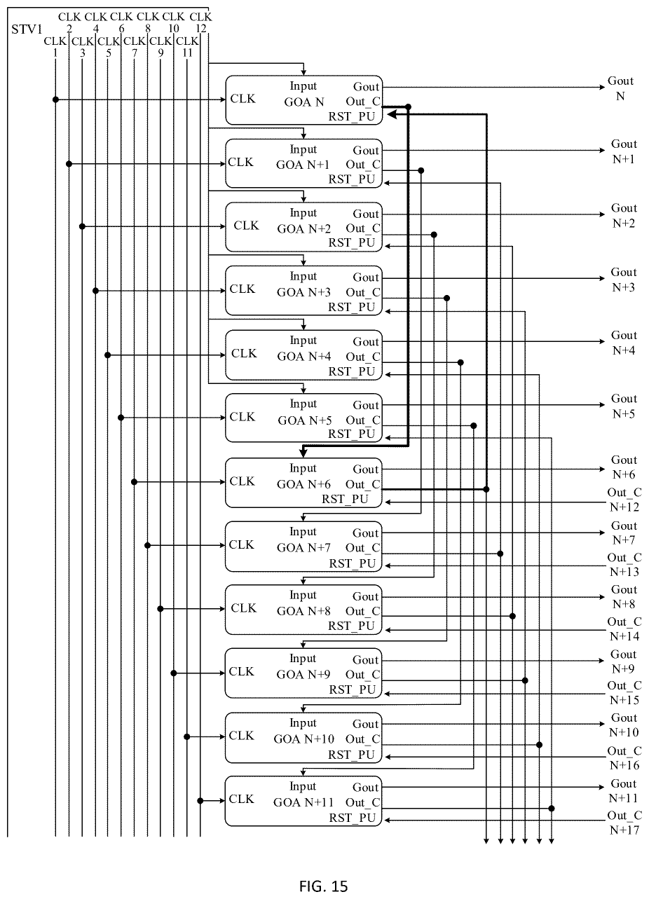

The cascade relationship of the shift registers in the scheme 2 is introduced below. Referring to FIG. 15, the array substrate includes at least two gate driving circuits, and the gate driving circuit includes a plurality of cascaded shift registers.

The input signal terminals of the first six-levels of shift registers are configured to be coupled to the frame initial signal terminal, so as to provide an initial signal to the input terminal of the initial-level of the shift register.

In every six adjacent shift registers, the input signal terminal of the N+6th shift register is configured to be coupled to the cascade output terminal of the Nth shift register, and the reset signal terminal of the Nth shift register is configured to be coupled to the cascade output terminal of the N+6th shift register, where N is a positive integer.

During the implementation, the change in the connection relationship between the shift register and the clock signal line is used as an example for explanation. The cascade relationship of each shift register is as follows: the signal at the cascade output terminal of the first-stage shift register is given to the input signal terminal of the seventh-stage shift register, the signal at the cascade output terminal of the second-stage shift register is given to the input signal terminal of the eighth-stage shift register . . . and so on. The signal at the cascade output terminal of the seventh-stage shift register is provided to the reset signal terminal of the first-stage shift register, the signal at the cascade output terminal of the eighth-stage shift register is provided to the reset signal terminal of the second-stage shift register . . . and so on.

In some embodiments, the frame initial signal terminal can be provided by an initial signal line. Referring to FIG. 15, the array substrate further includes a first initial signal line, and the first initial signal line is coupled to the frame initial signal terminal.

The input signal terminals of the 1st-stage shift register to the 2Mth-stage shift register are connected to the first initial signal line.

That is, the frame initial signal terminals of the 2M shift registers in the embodiment of the present disclosure are all provided by the signal in the first initial signal line.

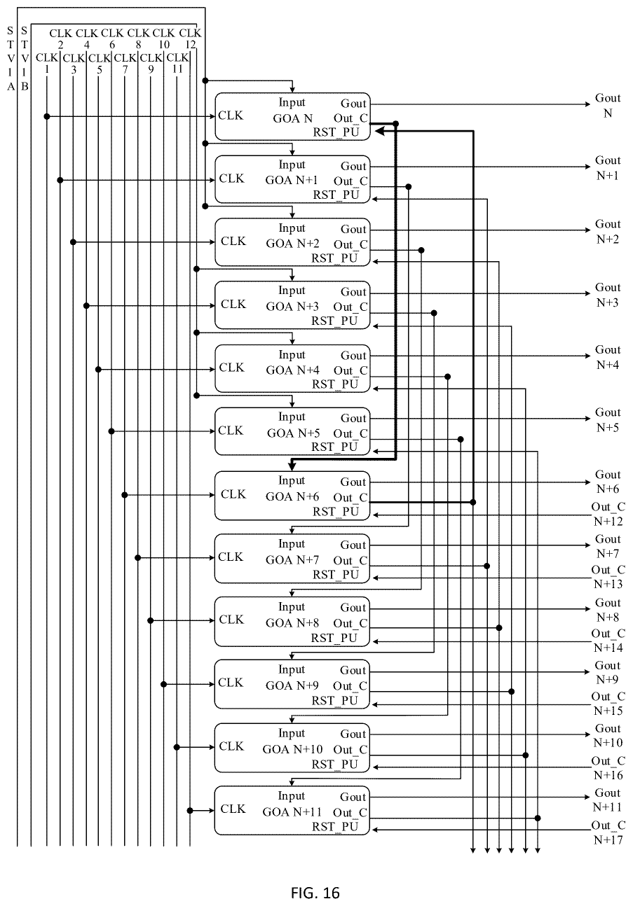

In other embodiments, the frame initial signal terminal can be provided by two initial signal lines. Referring to FIG. 16, in one embodiment, the array substrate further includes a second initial signal line and a third initial signal line. The second initial signal line is coupled to the first frame initial signal terminal, and the third initial signal line is coupled to the second frame initial signal terminal. Referring to FIG. 16, the two initial signal lines are STV1A and STV1B, the input signal terminals of the first three-levels of GOA are controlled by the initial signal STV1A, and the input signal terminals of the fourth, fifth and sixth-levels of GOA are controlled by the initial signal STV1B. With such a design, the half number of GOA can be controlled to be n and the other half number of GOA can be controlled to be off, which is used for PDF (pattern detect) functions, etc.

The input signal terminals of the 1st-stage shift register to the Mth-stage shift register are connected to the second initial signal line, and the input signal terminals of the Mth-stage shift register to the 2Mth-stage shift register are connected to the third initial signal line.

That is, the frame initial signal terminals of the first M shift registers in the embodiment of the present disclosure are provided by the signal in the second initial signal line, and the frame initial signal terminals of the last M shift registers in the embodiment of the present disclosure is provided by the signal in the third initial signal line.

Based on the same inventive concept, an embodiment of the present disclosure provides a display device, including: an array substrate according to any one of the above items.

In the embodiment of the present disclosure, the display device may be any product or component with a display function, such as a mobile phone, a tablet computer, a television, a monitor, a laptop computer, a digital photo frame, a navigator, etc. Other essential components of the display device are well understood by those skilled in the art, and are not described in detail herein, nor should they be used as limitations on the present disclosure.

Based on the same inventive concept, an embodiment of the present disclosure provides a driving method, including:
in the first mode, the same clock signal is loaded onto the clock signal lines connected to the same register group, and clock signals with a first phase difference are loaded onto the clock signal lines connected to two adjacent register groups.

In an embodiment of the present disclosure, when the array substrate operates in the DLG mode, in order to prevent interference in the color display of two sub-pixels of the same color corresponding to the same register group, the same clock signal is loaded on the clock signal line connected to the same register group. In the specific implementation process, in one way, the connection relationship between the output of the shift register in the non-display region and the sub-pixels in the display region is changed, so that the clock signals on the clock signal line connected to the two shift registers in the same register group can be the same, thereby ensuring that the gate lines of the two shift registers in the same register group can simultaneously provide drive signals to the two sub-pixel rows of the same color included in the corresponding row unit; in another way, the connection relationship between the output of the shift register in the non-display region and the sub-pixels in the display region is not changed, and the driving timing of CLK is changed, so that the gate lines of the two shift registers in the same register group can simultaneously provide drive signals to the two sub-pixel rows of the same color included in the corresponding row unit.

In summary, in the embodiments of the present disclosure, an array substrate, a display device and a driving method are provided. The array substrate includes: a display region and a non-display region, where the display region includes a plurality of rows of gate lines and a plurality of columns of data lines. The plurality of rows of gate lines and the plurality of columns of data lines intersect to define a plurality of sub-pixel rows, where the sub-pixel rows includes pixel electrodes and transistors. The sides of the pixel electrodes extending along the gate lines are longer than the sides of the pixel electrodes extending along the data lines. The non-display region includes a plurality of cascaded shift registers, and the display region includes a plurality of row groups repeatedly arranged along a column direction. Each row group includes: M sub-pixel rows of different colors arranged along a column direction. The sub-pixels in the same sub-pixel row have the same color, and two sub-pixel rows of the same color in two adjacent row groups are a row unit. The plurality of cascaded shift registers include a plurality of register groups, where each register group includes two shift registers. The two shift registers are adjacently arranged or there are M−1 shift registers between the two shift registers. One register group corresponds to one row unit, the first shift register in the register group is connected to the first sub-pixel row in the corresponding row unit, and the second shift register is connected to the second sub-pixel row in the corresponding row unit. The array substrate also includes multiple clock signal lines. Each shift register is connected to a clock signal line. When the array substrate works in the first mode, the clock signals on the clock signal lines connected to the same register group are the same, and the clock signals on the clock signal lines connected to two adjacent register groups have a first phase difference. The above-mentioned sub-pixel rows of the same color that are connected by the same data line are turned on in sequence and driven by the same clock signal, which effectively improves the display effect of the picture, reduces the cost, and improves the charging rate of the array substrate.

Those skilled in the art will appreciate that the embodiments of the present disclosure may be provided as methods, systems, or computer program product systems. Therefore, the present disclosure may take the form of a complete hardware embodiment, a complete software embodiment, or an embodiment combining software and hardware. Moreover, the present disclosure may take the form of a computer program product system implemented on one or more computer-usable storage media (including but not limited to disk storage, CD-ROM, optical storage, etc.) containing computer-usable program codes.

The present disclosure is described with reference to the flowchart and/or block diagram of the method, device (system), and computer program product system according to the present disclosure. It should be understood that each process and/or box in the flowchart and/or block diagram, as well as the combination of the process and/or box in the flowchart and/or block diagram can be implemented by computer program instructions. These computer program instructions can be provided to a processor of a general-purpose computer, a special-purpose computer, an embedded processor or other programmable data processing device to produce a machine, so that the instructions executed by the processor of the computer or other programmable data processing device produce a device for implementing the functions specified in one process or multiple processes in the flowchart and/or one box or multiple boxes in the block diagram.

These computer program instructions may also be stored in a computer-readable memory that can direct a computer or other programmable data processing device to work in a specific manner, so that the instructions stored in the computer-readable memory produce a manufactured product including an instruction device that implements the functions specified in one or more processes in the flowchart and/or one or more boxes in the block diagram.

These computer program instructions may also be loaded onto a computer or other programmable data processing device so that a series of operational steps are executed on the computer or other programmable device to produce a computer-implemented process, whereby the instructions executed on the computer or other programmable device provide steps for implementing the functions specified in one or more processes in the flowchart and/or one or more boxes in the block diagram.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is also intended to include these modifications and variations.

1. An array substrate, comprising: a display region and a non-display region, wherein the display region comprises a plurality of rows of gate lines and a plurality of columns of data lines, the plurality of rows of gate lines and the plurality of columns of data lines intersect to define a plurality of sub-pixel rows, the sub-pixel rows comprise pixel electrodes and transistors, a side of a pixel electrode extending along an extending direction of the gate lines is longer than a side of the pixel electrode extending along an extending direction of the data lines;
the non-display region comprises a plurality of cascaded shift registers;
the display region comprises a plurality of row groups repeatedly arranged along the extending direction of the data lines, each of the row groups comprises: M sub-pixel rows of different colors arranged along the column direction, and sub-pixels in a same sub-pixel row are of a same color, wherein M is a positive integer;
two sub-pixel rows of the same color in two adjacent row groups form one of row units;
the plurality of cascaded shift registers comprise a plurality of register groups, each of the register groups comprises two shift registers, wherein the two shift registers are arranged adjacent to each other, or there are M−1 shift registers between the two shift registers;
one of the register groups corresponds to one of the row units;
a first shift register in a register group is connected to a first sub-pixel row in a row unit corresponding to the register group, and a second shift register in the register group is connected to a second sub-pixel row in the row unit corresponding to the register group;
wherein the array substrate further comprises a plurality of clock signal lines, and each of the cascaded shift registers is connected to a respective one of the clock signal lines;
wherein based on that the array substrate operating in a first mode, clock signals on clock signal lines connected to a same register group are the same, and clock signals on clock signal lines connected to two adjacent register groups are of a first phase difference.

2. The array substrate according to claim 1, wherein an operating mode of the array substrate further comprises a second mode;
based on that the array substrate operating in the second mode, the clock signals on the clock signal lines connected to the same register group are of a second phase difference, and the clock signals on the clock signal lines connected to the two adjacent register groups are of the second phase difference.

3. The array substrate according to claim 2, wherein the first phase difference is twice the second phase difference.

4. The array substrate according to claim 2, wherein a width of a data signal loaded into the row unit is 2H, wherein H is a charging time of one sub-pixel row.

5. The array substrate according to claim wherein each of the row groups comprises: a first color sub-pixel row, a second color sub-pixel row, and a third color sub-pixel row arranged along the column direction;
wherein based on that the array substrate operating in the first mode, a timing of a clock signal corresponding to a shift register connected to the first color sub-pixel row is earlier than a timing of a clock signal corresponding to a shift register connected to the second color sub-pixel row, and the timing of the clock signal corresponding to the shift register connected to the second color sub-pixel row is earlier than a timing of a clock signal corresponding to a shift register connected to the third color sub-pixel row.

6. The array substrate according to claim 5, wherein connection relationships between shift registers and clock signal lines are as follows:
a 12k-11th-level shift register is connected to a first clock signal line of the plurality of clock signal lines;
a 12k-10th-level shift register is connected to a second clock signal line of the plurality of clock signal lines;
a 12k-9th-level shift register is connected to a third clock signal line of the plurality of clock signal lines;
a 12k-8th-level shift register is connected to a fourth clock signal line of the plurality of clock signal lines;
a 12k-7th-level shift register is connected to a fifth clock signal line of the plurality of clock signal lines;
a 12k-6th-level shift register is connected to a sixth clock signal line of the plurality of clock signal lines;
a 12k-5th-level shift register is connected to a seventh clock signal line of the plurality of clock signal lines;
a 12k-4th-level shift register is connected to an eighth clock signal line of the plurality of clock signal lines;
a 12k-3th-level shift register is connected to a ninth clock signal line of the plurality of clock signal lines;
a 12k-2th-level shift register is connected to a tenth clock signal line of the plurality of clock signal lines;
a 12k-1th-level shift register is connected to an eleventh clock signal line of the plurality of clock signal lines;
a 12kth-level shift register is connected to a twelfth clock signal line of the multiple clock signal lines, wherein k is a positive integer.

7. The array substrate according to claim 5, further comprising at least two gate driving circuits, wherein the gate driving circuits comprise the plurality of cascaded shift registers;
an input signal terminal of a first-level shift register is configured to be coupled to a frame initial signal terminal;
wherein in every six adjacent shift registers, an input signal terminal of a 6Mth-level shift register is configured to be coupled to an output terminal of a 6M−5th-level shift register, and a reset signal terminal of the 6M−5th-level shift register is configured to be coupled to an output terminal of a 6M+Nth-level shift register, wherein N is a positive integer.

8. The array substrate according to claim 7, further comprising a first initial signal line, wherein the first initial signal line is coupled to the frame initial signal terminal;
input signal terminals of the first-level shift register to a 2Mth-level shift register are connected to the first initial signal line.

9. The array substrate according to claim 7, further comprising a second initial signal line and a third initial signal line, wherein the second initial signal line is coupled to a first frame initial signal terminal, and the third initial signal line is coupled to a second frame initial signal terminal;
input signal terminals of the first-level shift register to a Mth-level shift register are connected to the second initial signal line, and input signal terminals of the M+1th-level shift register to a 2Mth-level shift register is connected to the third initial signal line.

10. The array substrate according to claim 7, wherein sub-pixels located in different rows and connected to a same data line are arranged on both sides of the same data line.

11. The array substrate according to claim 7, wherein sub-pixels in different rows and connected to a same data line are arranged on a same side of the same data line.

12. A display device, comprising an array substrate, wherein the array substrate comprises:
a display region and a non-display region, wherein the display region comprises a plurality of rows of gate lines and a plurality of columns of data lines, the plurality of rows of gate lines and the plurality of columns of data lines intersect to define a plurality of sub-pixel rows, the sub-pixel rows comprise pixel electrodes and transistors, a side of a pixel electrode extending along an extending direction of the gate lines is longer than a side of the pixel electrode extending along an extending direction of the data lines;
the non-display region comprises a plurality of cascaded shift registers;
the display region comprises a plurality of row groups repeatedly arranged along the extending direction of the data lines, each of the row groups comprises: M sub-pixel rows of different colors arranged along the column direction, and sub-pixels in a same sub-pixel row are of a same color, wherein M is a positive integer;
two sub-pixel rows of the same color in two adjacent row groups form one of row units;
the plurality of cascaded shift registers comprise a plurality of register groups, each of the register groups comprises two shift registers, wherein the two shift registers are arranged adjacent to each other, or there are M−1 shift registers between the two shift registers;
one of the register groups corresponds to one of the row units;
a first shift register in a register group is connected to a first sub-pixel row in a row unit corresponding to the register group, and a second shift register in the register group is connected to a second sub-pixel row in the row unit corresponding to the register group;
wherein the array substrate further comprises a plurality of clock signal lines, and each of the cascaded shift registers is connected to a respective one of the clock signal lines;
wherein based on that the array substrate operating in a first mode, clock signals on clock signal lines connected to a same register group are the same, and clock signals on clock signal lines connected to two adjacent register groups are of a first phase difference.

13. A driving method, comprising:
in a first mode, loading a same clock signal onto clock signal lines connected to a same register group, and loading clock signals with a first phase difference onto clock signal lines connected to two adjacent register groups.

14. The display device according to claim 12, wherein an operating mode of the array substrate further comprises a second mode;
based on that the array substrate operating in the second mode, the clock signals on the clock signal lines connected to the same register group are of a second phase difference, and the clock signals on the clock signal lines connected to the two adjacent register groups are of the second phase difference.

15. The display device according to claim 14, wherein the first phase difference is twice the second phase difference.

16. The display device according to claim 14, wherein a width of a data signal loaded into the row unit is 2H, wherein H is a charging time of one sub-pixel row.

17. The display device according to claim 14, wherein each of the row groups comprises: a first color sub-pixel row, a second color sub-pixel row, and a third color sub-pixel row arranged along the column direction;
wherein based on that the array substrate operating in the first mode, a timing of a clock signal corresponding to a shift register connected to the first color sub-pixel row is earlier than a timing of a clock signal corresponding to a shift register connected to the second color sub-pixel row, and the timing of the clock signal corresponding to the shift register connected to the second color sub-pixel row is earlier than a timing of a clock signal corresponding to a shift register connected to the third color sub-pixel row.

18. The display device according to claim 17, wherein connection relationships between shift registers and clock signal lines are as follows:
a 12k-11th-level shift register is connected to a first clock signal line of the plurality of clock signal lines;
a 12k-10th-level shift register is connected to a second clock signal line of the plurality of clock signal lines;
a 12k-9th-level shift register is connected to a third clock signal line of the plurality of clock signal lines;
a 12k-8th-level shift register is connected to a fourth clock signal line of the plurality of clock signal lines;
a 12k-7th-level shift register is connected to a fifth clock signal line of the plurality of clock signal lines;
a 12k-6th-level shift register is connected to a sixth clock signal line of the plurality of clock signal lines;
a 12k-5th-level shift register is connected to a seventh clock signal line of the plurality of clock signal lines;
a 12k-4th-level shift register is connected to an eighth clock signal line of the plurality of clock signal lines;
a 12k-3th-level shift register is connected to a ninth clock signal line of the plurality of clock signal lines;
a 12k-2th-level shift register is connected to a tenth clock signal line of the plurality of clock signal lines;
a 12k-1th-level shift register is connected to an eleventh clock signal line of the plurality of clock signal lines;
a 12kth-level shift register is connected to a twelfth clock signal line of the multiple clock signal lines, wherein k is a positive integer.

19. The display device according to claim 17, further comprising at least two gate driving circuits, wherein the gate driving circuits comprise the plurality of cascaded shift registers;
an input signal terminal of a first-level shift register is configured to be coupled to a frame initial signal terminal;
wherein in every six adjacent shift registers, an input signal terminal of a 6Mth-level shift register is configured to be coupled to an output terminal of a 6M−5th-level shift register, and a reset signal terminal of the 6M−5th-level shift register is configured to be coupled to an output terminal of a 6M+Nth-level shift register, wherein N is a positive integer.

20. The display device according to claim 19, further comprising a first initial signal line, wherein the first initial signal line is coupled to the frame initial signal terminal;
input signal terminals of the first-level shift register to a 2Mth-level shift register are connected to the first initial signal line.
